(19) United States
(12) Patent Application Publication
(10) Pub. No.: US 2022/0028704 A1
(43) Pub. Date: Jan. 27, 2022

(54) MOLDED PACKAGES IN A MOLDED DEVICE

(71) Applicant: OCTAVO SYSTEMS LLC, Sugar Land, TX (US)

(72) Inventors: Masood MURTUZA, Sugar Land, TX (US); Gene Alan FRANTZ, Sugar Land, TX (US)

(73) Assignee: OCTAVO SYSTEMS LLC, Sugar Land, TX (US)

(21) Appl. No.: 17/414,237

(22) PCT Filed: Dec. 18, 2019
(86) PCT No.: PCT/US2019/067096

§ 371 Date: Jun. 15, 2021

Related U.S. Application Data
(60) Provisional application No. 62/781,320, filed on Dec. 18, 2018.

(51) Int. Cl. H01L 21/56; H01L 23/13; H01L 23/31; H01L 23/552; H01L 23/00; H01L 21/48; G06F 30/20

(52) U.S. Cl. CPC H01L 21/563; H01L 23/13; H01L 23/3128; H01L 23/315; H01L 23/552; H01L 2924/15151; H01L 21/4803; G06F 30/20; H01L 2224/16225; H01L 2224/1601; H01L 24/16

(57) ABSTRACT

Packaged devices are provided for use inside an electronic system that provides access for molding compound or cables by using groove-like features on the bottom of a device package or on top of a substrate, and methods regarding the same. The groove-like features prevent voids in the encapsulant before and after packaging of the electronic system.

### TECHNICAL FIELD

Aspects of the present disclosure relate to packaged electronic devices and manufacture, including providing a packaged component in a molded device (e.g., SiP) without voids underneath and around the packaged component.

### BACKGROUND

System in Package (SiP) technology allows the integration into one package of multiple die, devices, and components needed to make up a system or subsystem. As more diverse process technologies are used to manufacture die, SiPs are becoming useful for including and integrating all these various components into a system or subsystem. These system components need to meet the same expectations of package mechanical integrity and reliability as any other semiconductor component.

In SiP molded packages, different types of devices and components may be assembled on a substrate prior to encapsulation. These devices and components may be passive devices and bare die or pre-packaged IC devices. In some non-limiting examples, the passive devices may be capacitors, inductors, and resistors, and the bare die or pre-packaged IC devices may be DRAM, CPU, or other ICs. Typically, a SiP is encapsulated as part of the final packaging process. The encapsulating material (hereinafter referred to as “encapsulant”), also referred to as a molding compound (in the context of the current disclosure, the terms molding compound and encapsulant are used interchangeably), can be, for example, a thermosetting plastic material with fillers, such as silica. Typically, when the molding compound is heated up to a certain temperature, the molding compound melts and attains a very low viscosity to become a fluid for a short period of time, and then the molding compound gels and hardens into a solid. It is important to completely fill above, around, and below the package mold cavity with the molding compound while it is in liquid form.

In the case of a SiP, it is desirable that the liquid form should not only fill the mold cavity but also fill around and below the components that have been previously mounted on the SiP substrate. In general, the passives and IC packages may be mounted on a SiP substrate such that each of these devices and components have sufficient clearance above the SiP substrate for encapsulant to flow between the bottom of the device/component and the substrate. However, it is desirable for this spacing to allow the encapsulant to flow underneath the device/component and all around it without any voids in order to form a void free SiP package.

If the resulting SiP molded package contains voids (e.g., air gaps), these voids may cause several problems, such as for example, but not limited to, condensation of moisture and related degradation of components, substrate, or a package, popping off the package during surface mounting, cracking, corrosion, and current leakage resulting from corrosion. Depending on the selected encapsulant, voids may accumulate moisture which may create unwanted electrical paths, thereby reducing the expected life of a system. In system applications which are exposed to high pressure and/or vacuum environments, voids may further create a pressure stabilization problem for the system.

### SUMMARY

The inclusion of packaged components in a SiP package presents challenges for the encapsulation and packaging process. There remains a need for effective ways to encapsulate a packaged circuit or component inside of a second molded package.

According to some embodiments, a packaged circuit or component may be used inside a second molded package for an electronic system or subsystem. The system or subsystem may be a single chip, a multichip package, a sub-system, or a System-in-Package (SiP) device.

In addition to components in encapsulated packages, other structures may be used in the SiP package that are not encapsulated but include cables or wires that are to be routed inside a SiP package. In some embodiments, access for the molding compound is enabled by creating channel-like features on the surfaces of the packaged component (e.g., side surfaces, top surfaces, bottom surfaces) and/or in a top surface of the SiP substrate to allow any entrapped gases or air to escape. In some embodiments, the channel-like features may be created by creating channel-like path-ways under an already packaged component by providing grooves in the bottom of the package. For example, a molded/packaged component may have grooves in the bottom of the package between arrays of balls of a Ball Grid Array (BGA). In some embodiments, these grooves may be made in the SiP's substrate on a surface upon which the packaged device or component is to be located. In some embodiments, the total flow pattern of the molding compound under or around the molded component may be modified by adjusting the gap between the component and the substrate. In some embodiments, a narrow gap between the component and the substrate may accelerate the flow under the component thereby avoiding entrapment of air. In some embodiments, the gap between the component and the substrate may be sufficiently increased to allow a uniform flow of liquid molding compound under a packaged component or device. Such variation in the gap between the component and the substrate may be implemented by controlling the collapse of balls or the size of the balls of an embedded ball grid array (BGA) package, the solder mask size, and/or thickness on the substrate during the soldering process.

According to embodiments, a packaged integrated circuit device (e.g., SiP) is provided that comprises a substrate, and a packaged component attached to said substrate. The packaged component comprises at least one vent on a bottom surface of said packaged component. In certain aspects, the encapsulant between the packaged component and said substrate contains no voids in a region adjacent said vent on said bottom surface of said packaged component. In some embodiments, a radiation blocking or sensitive element can be mounted on the substrate, for instance, over a vent in a top surface of the substrate. The vent in the substrate may be, for example, an opening that extends entirely through the substrate. The radiation blocking or sensitive element may itself comprise one or more vents. For instance, the packaged component may be a radiation blocking or sensitive element.

According to embodiments, a method for packaging an integrated circuit device (e.g., SiP) is provided. The method may begin with the step of providing a substrate. The method may further comprise: attaching a packaged component to said substrate, wherein the packaged component comprises a vent on a bottom surface of said packaged component, wherein the bottom surface of the packaged component faces a top surface of the substrate; placing said substrate and the attached packaged component in a packaging mold; and injecting an encapsulant into the packaging mold to create a package enclosing the substrate and the packaged component. In certain aspects, the encapsulant flows between the substrate and the packaged component, and any void formation while enclosing the substrate and the packaged component with the encapsulant is prevented by said vent, and the vent itself is configured to allow gases trapped in the encapsulant to escape. In some embodiments, the method includes operatively mounting a plurality of other devices and components on said substrate before injecting the encapsulant into the packaging mold.

According to some embodiments, a method for creating a substrate for a SiP device containing at least one packaged component using a scale model of the SiP device containing at least one packaged component and said substrate is provided, where said at least one packaged component is attached to a surface of the substrate. The method may begin, for instance, with the step of simulating the flow of liquid encapsulant through said scale model of the SiP device. The method may further comprise the steps of: analyzing the simulation for any voids in the encapsulant between any one of the at least one packaged component and the substrate; modifying said design of said SiP model to mitigate any voids, wherein modifying the design includes modifying said substrate which comprises any one of: modifying the substrate to include one or more vents or holes on a surface, and modifying any existing vents or holes on the substrate to mitigate any voids and modifying at least one of the at least one packaged components to include vents on its bottom mounting surface, modifying existing vents in said bottom mounting surface to mitigate any voids; simulating the flow of encapsulant for packaging the scale model of the SiP device using the modified design of the substrate; and analyzing the simulation for any voids between the packaged component and the modified design of the substrate. The method may further comprise repeating the simulations with incremental substrate modifications until there are no voids between the packaged component and the modified design of the substrate, and then creating the substrate with the modified design of the substrate that result in no voids.

According to embodiments, a method is provided for designing a substrate for a SiP device containing at least one packaged component. The method comprises, for instance: creating a substrate design for said SiP device, wherein the substrate design comprises at least one vent over which each packaged component is to be mounted; manufacturing the substrate for the SiP device, wherein the substrate comprises the at least one vent for each packaged component; assembling SiP components and at least one packaged component on said substrate; and encapsulating the components into a SiP package. The method may further comprise mounting an RF generating or sensitive packaged component mounted on said substrate, and assembling a radiation blocking element having at least one opening in at least one side adjacent said substrate over said RF generating or sensitive packaged component. In some embodiments, said one or more vents comprise additional structures, channels, grooves, and holes.

According to embodiments, a method is provided for creating a void free SiP device using a substrate containing at least one packaged device. The method comprises, for instance, assembling the SiP device, wherein assembling the SiP device comprises assembling SiP components on said substrate including said at least one packaged device; encapsulating said SiP to package said SiP; testing said packaged SiP device for voids; detecting the presence of voids in said packaged SiP; modifying the design of said substrate or components to include vents, or modify any existing vents to determine if further testing determines that existing or modified vents mitigate any voids, modifying the design of said SiP to properly space any included packaged devices or other devices or components to determine if testing determines that spacing mitigates any voids; encapsulating said SiP using said modified design of said substrate, components and SiP; analyzing said packaged SiP employing said modified design of said substrate and SiP simulation for any voids in said package; continuing the foregoing steps with additional incremental substrate, component, and SiP design modifications until there are no voids; and assembling said SiP using said modified substrate and SiP design.

These and other features of the present disclosure will become apparent to those skilled in the art from the following detailed description of the disclosure, taken together with the accompanying drawings.

### BRIEF DESCRIPTION OF THE DRAWINGS

FIG. 1 depicts a SiP before molding according to embodiments.

FIGS. 2A and 2B depict one or more voids.

FIGS. 3A and 3B depict one or more components according to embodiments.

FIGS. 4A and 4B depict one or more components according to embodiments.

FIGS. 5A and 5B depict one or more components according to embodiments.

FIGS. 6A, 6B, 6C and 6D depict one or more components in a SiP according to embodiments.

FIGS. 7A, 7B, 7C and 7D depict packaged system manufacturing methods according to embodiments.

FIGS. 8A, 8B and 8C depict one or more components in a SiP according to embodiments.

FIG. 9A depicts a SiP according to embodiments.

FIG. 9B depicts a system manufacturing method according to embodiments.

FIGS. 10A-10C depict structures used for shielding EMI radiation from an RF device in a SiP according to some embodiments.

FIGS. 11A and 11B depict a baffle feature according to some embodiments.

### DETAILED DESCRIPTION

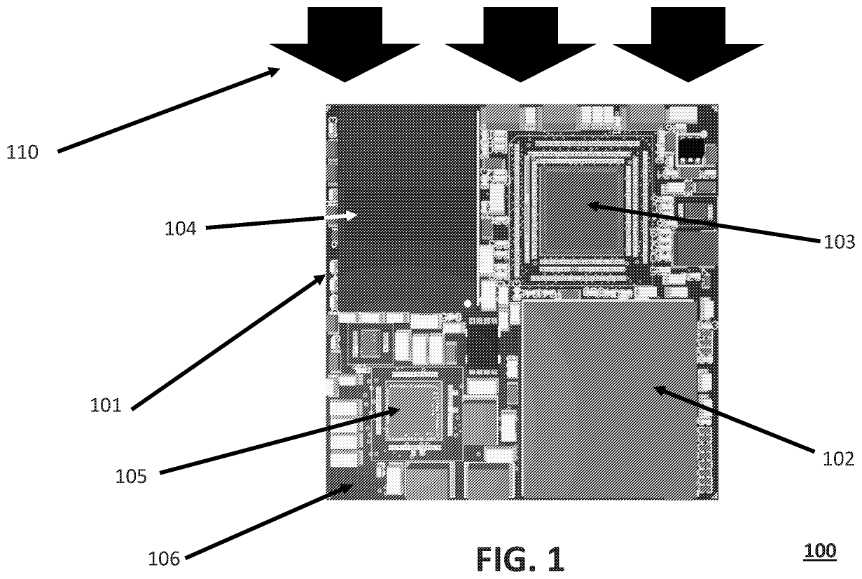

FIG. 1 depicts an example of a populated System in Package (SiP) 101 prior to being encapsulated. In this example, the SiP 101 comprises a substrate 106 on which many components have been attached prior to the encapsulation process. Some of the components may include, for instance, several integrated circuits in die form 103, 105, along with several packaged parts 102, 104, and other components. In this illustration, liquid encapsulant flows towards the SiP 101 in direction 110 in a mold form to package/encapsulate the SiP device 101. BGA packages can be molded, for example, by injecting molding compound at the correct temperature through openings (called “gates”) in the mold cavity or package form containing the SiP to be packaged. Molding compound is typically very fluid (i.e., has low viscosity) for a short period during which time it is injected into the mold cavity.

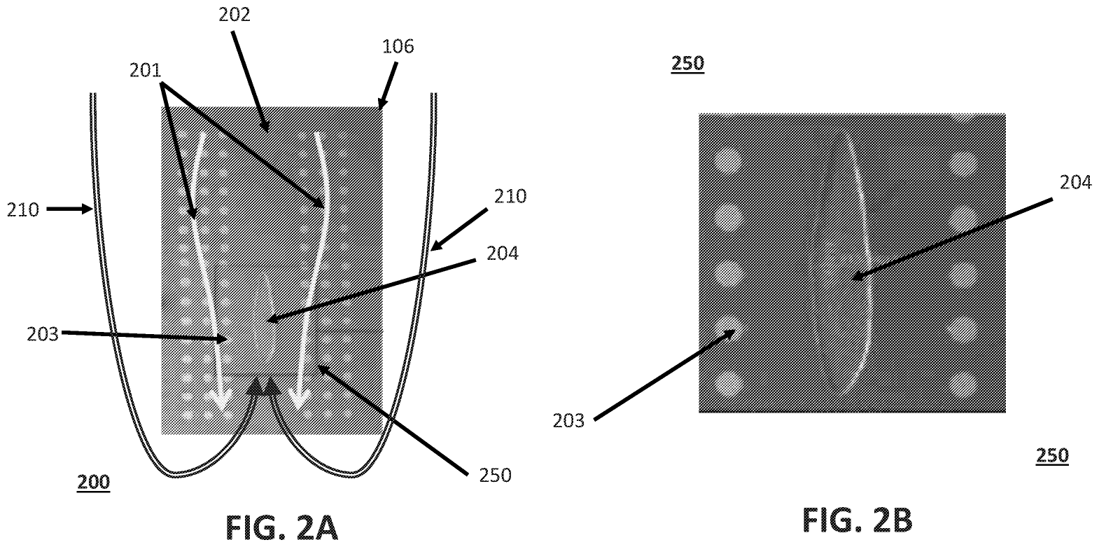

FIG. 2A depicts an enlarged partially see-though top view 200 of a portion of a component 202 (similar to item 104 of FIG. 1) attached to a substrate 106. In some embodiments, the component 202 may be a BGA packaged device. As shown in FIG. 2A, there is a void 204 under the packaged component 202 that has been formed when the packaged component 202 was attached to the substrate 104 and subjected to an encapsulant flow as part of a packaging process (an example of the packaging or encapsulation process is described with respect to FIG. 1). FIG. 2A illustrates a top view of the packaged component 202 after the encapsulant has been flowed into, through, and around the SiP in a packaging mold form. Also shown are two arrays of balls of the component, where one of the balls from the two arrays of balls is indicated as 203. The direction of the encapsulant flow in this example is indicated by the arrows 201. The other set of arrows 210 depict the flow of encapsulant around the sides or top of the packaged device resulting in a potential reverse flow of encapsulant under the package to trap gases between the two moving fronts of liquid encapsulant under the package and create the void 204.

The flow of liquid molding compound in a packaging mold form is subject to fluid flow properties. Fluid flow dynamics is a complex physics problem, but generally, for the same pressure, the flow rate for the liquid encapsulant or a fluid under a packaged device is faster where the area or cross section through which the encapsulant must pass is narrower or smaller. In this example, molding compound flows faster between the BGA balls 203 of the two arrays on the bottom surface of the BGA packaged component compared to the middle of the packaged component where there are no balls 203 as shown in FIG. 2A. This creates a liquid front that is moving faster between and in the balls arrays than in the middle portion with no balls, causing a deformed u-shaped front in which case any reverse flow front from outside the package may trap the open U portion and prevent it from filling with encapsulant, thereby creating the void 204. The encapsulant flow for the rest of the SiP is unhindered with a package, and will typically flow along faster than the flow under a packaged device, resulting in the reverse flow, when the encapsulant hits the end of the form for the SiP package. This may cause gases (e.g., air) to be trapped in these areas underneath a packaged device, thereby creating the void 204.

In some embodiments, the spacing above the packaged device is minimized by minimizing the thickness of the overall package, which results in slowing down the flow above and around the package to minimize any reverse flows. Alternatively, once the package form is completely filled with encapsulant, the pressure on the encapsulant may be increased to collapse any voids that may have formed.

Commercially available software, such as, for example, Moldflow by Autodesk and software provided by Beaumont, Moldex3D, Cadence or Mentor Graphics, for modeling fluid flow (liquid encapsulant) simulations during packaging of a SiP can be used to illustrate the creation of this type of void. Further, experiments when packaging a SiP have shown these types of voids under packaged devices using ultrasonic testing. However, when the overall SiP package is soldered to a board or substrate, the SiP package containing a packaged device is also heated up and problems may arise. The gases contained in any voids under the packaged device in the SiP will expand when heated, mechanically damaging the packaged SiP by deforming the substrate, delaminating the packaged device from the substrate, or rupturing the SiP package. The deformation can either cause a failed device or a reliability issue, for instance.

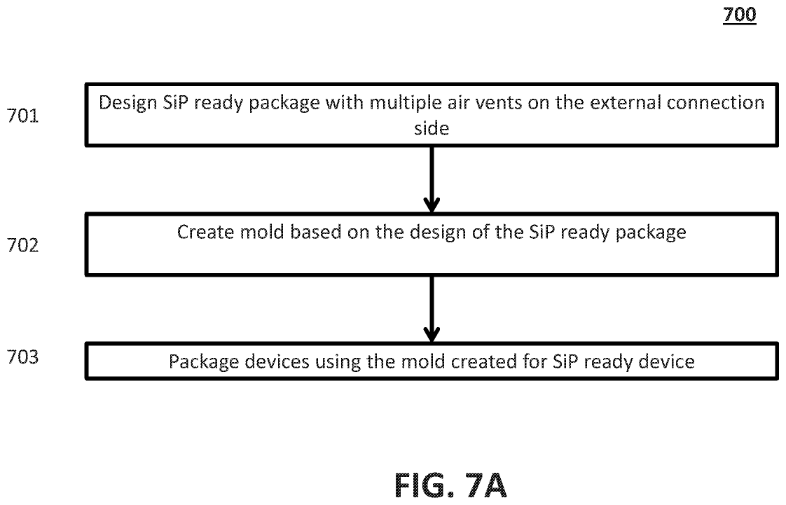

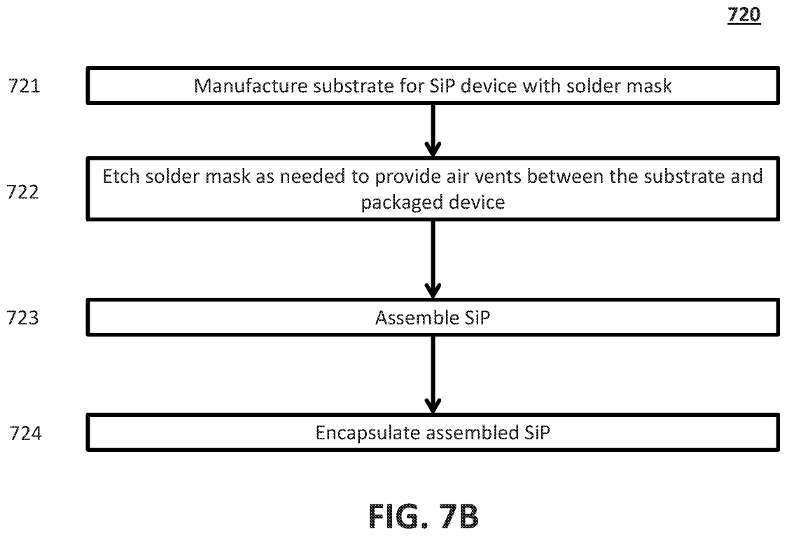

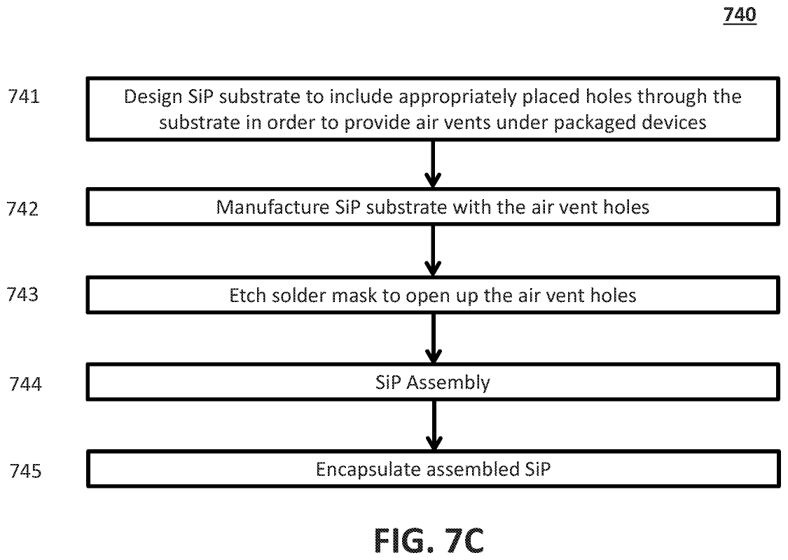

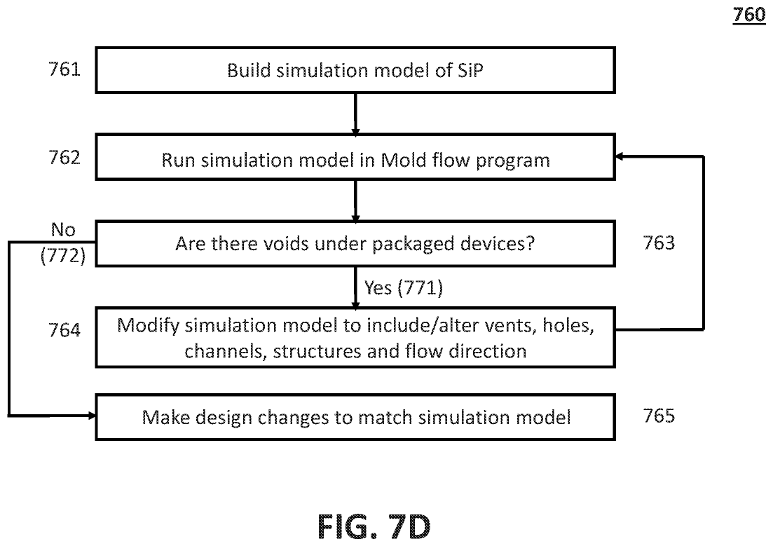

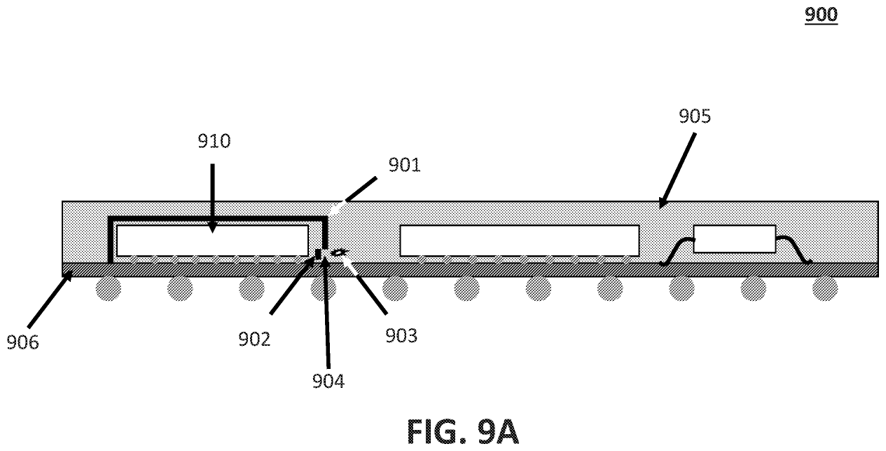

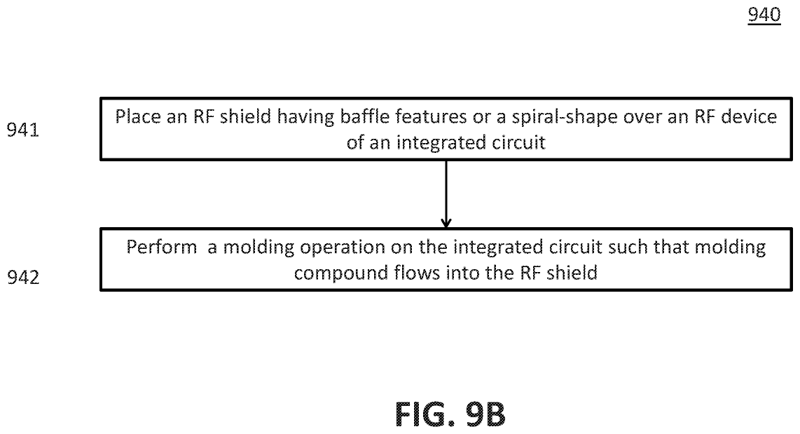

An alternative for eliminating these type of voids is to use a first fluid to provide an underfill layer for the packaged devices before the final encapsulation for the entire SiP package. According to embodiments, an underfill process is use in one or more encapsulation steps described herein, including one or more of the processes described with respect to FIGS. 7A-7D and 9B. In certain aspects, an underfill process is used when packaging parts that are, themselves, already packaged.

FIG. 2B depicts an enlarged top view of a portion 250 of the packaged component 202 including the void 204, as shown in FIG. 2A. The void 204 is typically filled with gases which may include, for example, but are not limited to manufacturing gasses, breathable air, and moisture. Such gases expand when heated, typically during a soldering process of a SiP package to a system board or substrate, and mechanical damage the SiP by deforming the substrate or causing the packaged device or component to at least partially separate from the substrate. The deformation can either cause a failed device or a reliability issue. Further, any moisture trapped in a void may interact with other circuitry in a SiP allowing for corrosion to occur over time. This effect may cause reliability issues through the product life of the SiP which are undetectable through the assembly and test processes used during a conventional manufacturing process.

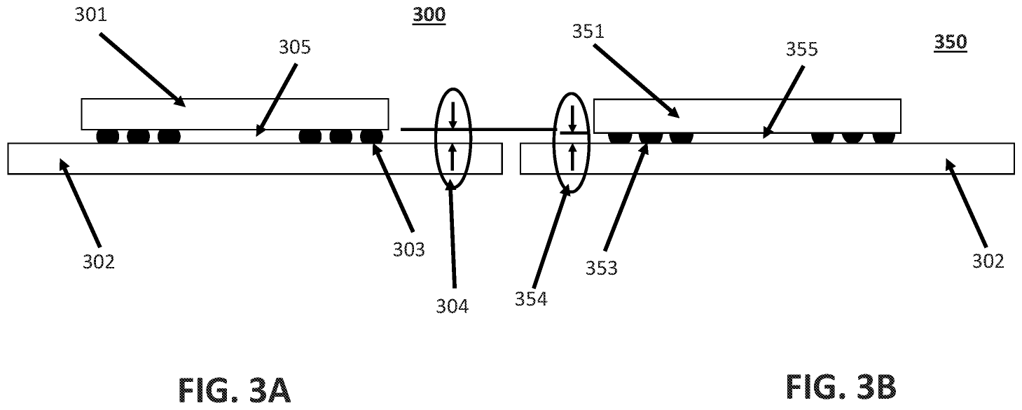

FIG. 3A depicts a side view 300 of a packaged component 301 attached to a substrate 302 using a Ball Grid Array (BGA) 303. Once the packaged component 301 is attached to the substrate 302, a space 305 is created between the packaged component 301 and the substrate 302. The space 305 may be represented as a distance 304, which may vary slightly within a small margin but remain relatively uniform across the area of the bottom of the packaged component 301. As a non-limiting example, the distance 304 may be a distance of approximately 150 um. In some embodiments, the spacing between the bottom of the packaged component 301 and the substrate 302 allows the liquid encapsulant to flow between the packaged component 301 and the substrate 302. However, as noted above, there is a potential for the creation of voids, such as air bubbles and air pockets, to form in the encapsulant in the space underneath the packaged component 301 once the encapsulant is solidified.

FIG. 3B depicts a side view 350 of a packaged component 351 attached to a substrate 302 using a BGA 353. In FIG. 3B the space 355 between the component and substrate represented as a distance 305, which is reduced compared to the distance 304 shown in FIG. 3A. In some embodiments, the reduced distance 354 provides sufficient spacing between the bottom of the packaged component 351 and the substrate 302 for the liquid encapsulant to flow between them. By reducing the distance 354 for the space 355 between the packaged component 351 and the substrate 302, the flow velocity of the encapsulant is sufficiently increased to drive or force any trapped air bubbles or voids to be swept out from under the bottom of the packaged component 351 and allow the encapsulant to escape out of the packaging mold form. In some embodiments, the distance 354 may be reduced by, for example, but not limited to, decreasing the solder mask thickness on the substrate 302, reducing the size of the solder balls 303, 353, or reducing the thickness of the solder paste. The overall flow velocity should not be increased so much that the liquid encapsulant front moves any bond wires of any bare die that are mounted on the substrate 302. The value of the new distance 354 will depend on a number of factors, including, for instance, manufacturer variations regarding spacing and tolerances.

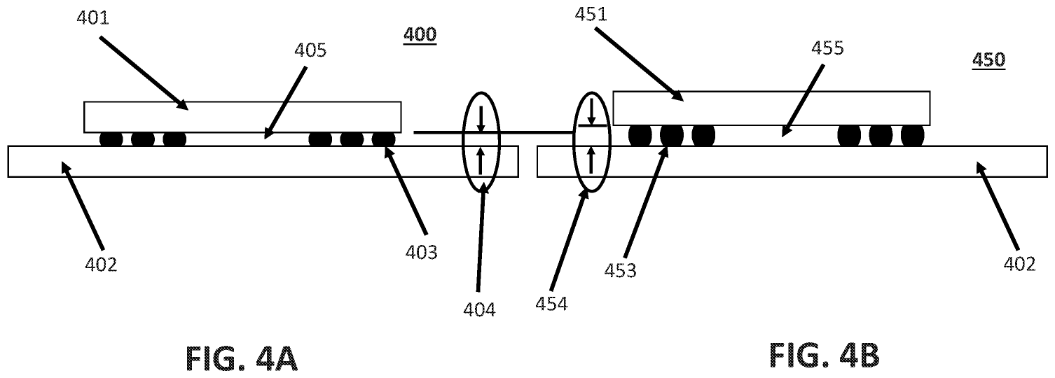

FIG. 4A depicts a side view 400 of a packaged component 401 attached to a substrate 402 using a Ball Grid Array (BGA) 403, according to some embodiments. Once the packaged component 401 is attached to the substrate 402, a space 405 is created between the packaged component 401 and the substrate 402. The space 405 may be depicted as a distance 404, which may vary slightly within a small margin but remain relatively uniform across the area of the bottom of the packaged component 401. As a non-limiting example, the space 405 may be represented as a distance 404 of approximately 150 um. In some embodiments, the spacing between the bottom of the packaged component 401 and the substrate 402 should enable the liquid encapsulant to flow freely between the packaged component 401 and the substrate 402. However, as noted above, there is a potential for the creation of voids, such as air bubbles and air pockets, to form in the encapsulant in the space underneath the packaged component 401 once the encapsulant is solidified.

FIG. 4B depicts a side view 450 of a packaged component 451 attached to a substrate 402 using a BGA 453. In FIG. 4B the space 454 is increased compared to the space 405 shown in FIG. 4A, such that distance 454 is greater than distance 404. In some embodiments, the space 405 is increased, for example, but not limited to, increasing the ball size 403, increasing the solder mask thickness on the substrate 402, or increasing the thickness of the solder paste. By increasing the distance between the packaged part 451 and the substrate 402, the flow velocity of the liquid encapsulant is sufficiently changed, e.g., reduced, to prevent creation and entrapment of voids, e.g., air bubbles. According to embodiments, this flow reduction results in prevention of the formation of voids that may be created by any vortices of the fluid encapsulant flowing around the balls of the packaged component, or from encapsulant flow coming from the other end of the packaged component 451 resulting from flow outside, over and around the package of component 451 and then a reverse flow back underneath the package 451 from the opposite end.

As shown above in FIGS. 3A, 3B, 4A, and 4B, voids may be prevented according to specific preselected encapsulant flow rates by either selectively reducing the distance 354 or increasing the distance 454. Accordingly, according to embodiments, the distance or height of the gap (304, 354, 404 and 454) is set such that the velocity of the liquid encapsulant is sufficient to prevent voids from either being created or captured under a packaged component. The height of the gap may be set by either employing a narrower gap or a wider gap. Variations may be determined, for instance, through the use of a modelling tool and simulations. Variables to consider, may include mold compound viscosity and filling rate.

Software such as, for example, Moldflow by Autodesk and software provided by Beaumont, Moldex3D, Cadence or Mentor Graphics, may be used to model the SiP and its components and then perform simulation based on that model of a SiP, its components, sizes, locations, and packages on its substrate and desired size of package mold and type of encapsulant being used, etc., to determine optimum spacing of components and packaged components above a substrate to minimize any voids.

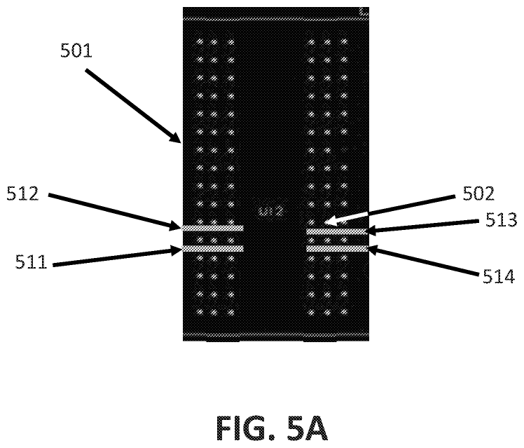

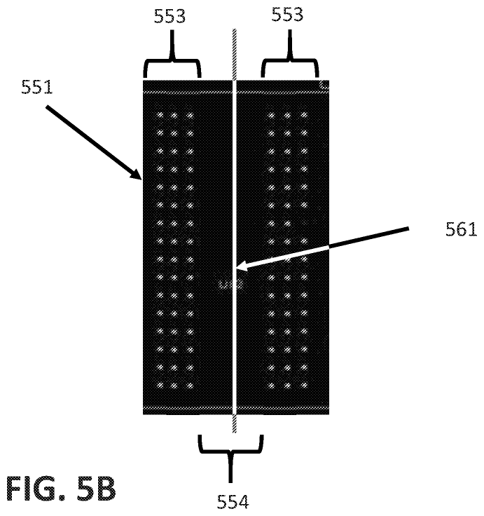

FIG. 5A depicts one embodiment for controlling encapsulant flows to minimize and/or prevent the formation of voids. As shown in FIG. 5A, vents 511, 512, 513, and 514 may be utilized between the packaged component 501 and the substrate (not shown in FIG. 5A) to provide multiple paths for any voids, such as air bubbles, that may form during the encapsulation process, thereby providing a new path for any trapped gasses to escape out from under the package 501. While this example uses 4 vents, any number of vents may be used in alternative embodiments. In FIG. 5A, the vents are implemented in the packaged device 501 and between the balls 502, among other components, of the packaged device 501. This is not required, however, and the vents may be located in any location that is optimal for the particular packaged component and substrate.

In some embodiments, vents may be used along a direction perpendicular to the longitudinal direction of a device. However, in some instances, an opposite or diagonal orientation may be used. Similarly, and according to embodiments, vents may be used in different directions within a given device, e.g., within a SiP. According to some embodiments, a vent pattern may be set or altered base on the specific flow of the encapsulant. For instance, a vent may be aligned perpendicularly to the direction of flow, or as another example, parallel to the direction of flow.

FIG. 5B depicts a vent 561 in a substrate (not shown in FIG. 5B) under the packaged device 551 vertically crossing through a large space 554 between two groups of balls 553a-b. According to embodiments, the vent 561 is narrow enough to allow any gasses formed during the encapsulation process to vent, but not wide enough to be easily filled with encapsulant. In some embodiments, the vent may comprise a diameter of 5 to 100 um. In some embodiments, the vent 561 may extend beyond the area under the package 551 in order to assure the gasses can vent beyond the packaged device. While FIG. 5B shows a single vent 561, any number of vents may be implemented in a certain pattern to the venting in alternative embodiments. In this example, the vents may be provided in the packaged components itself.

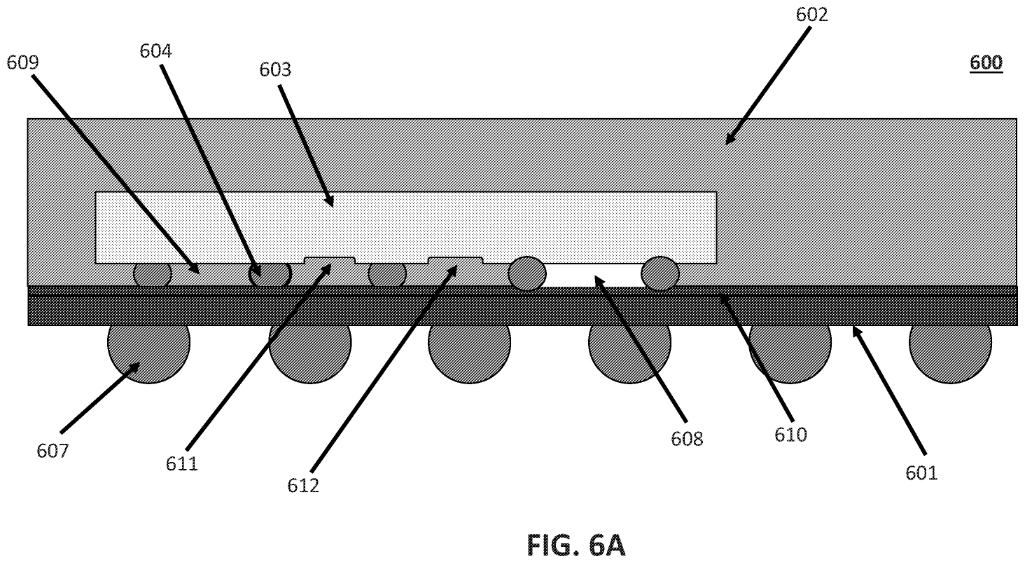

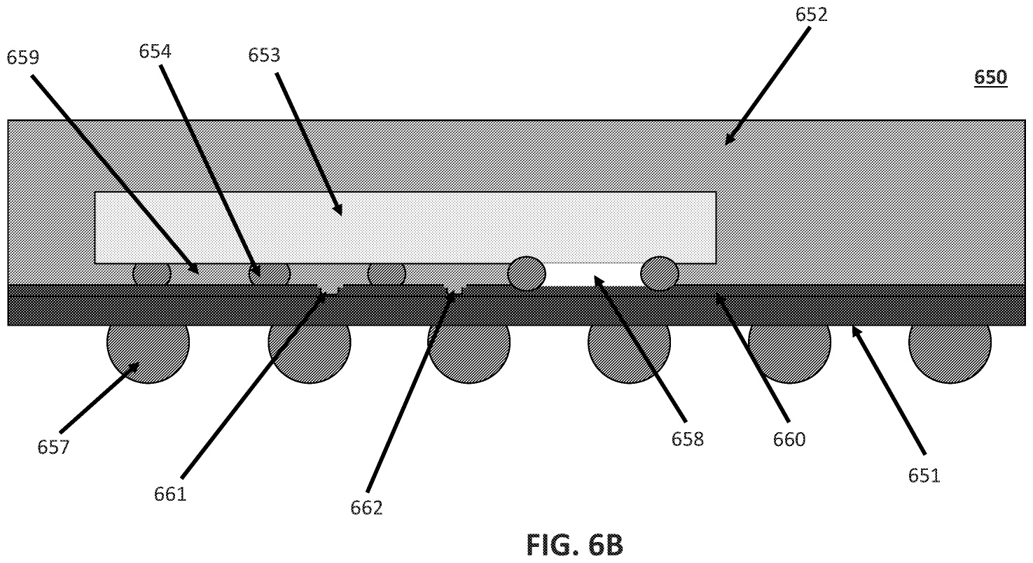

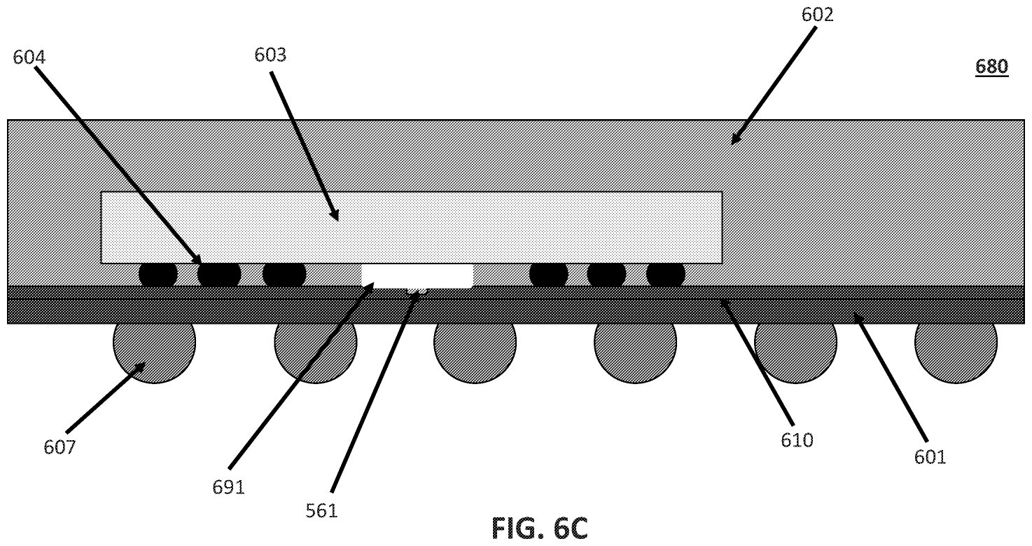

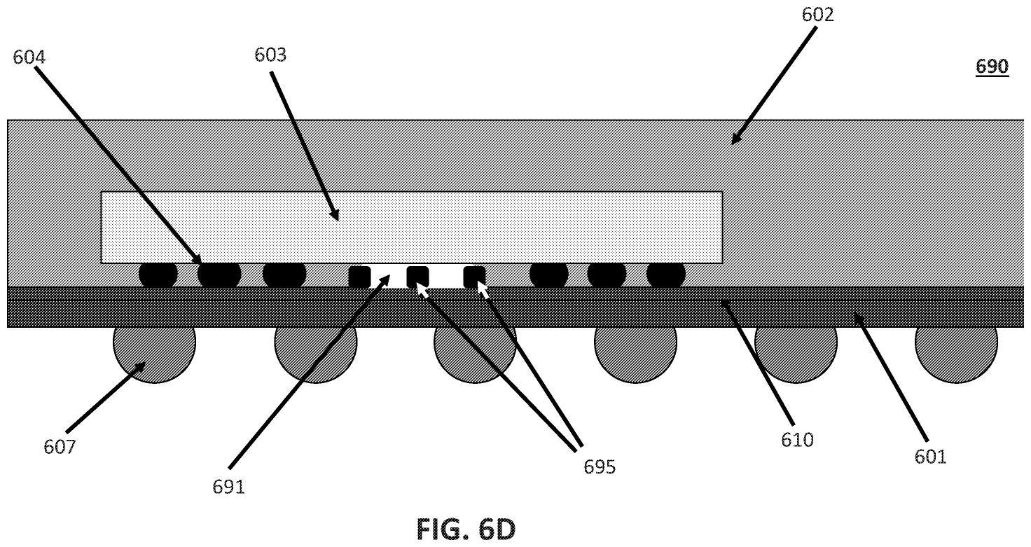

FIG. 6A depicts a cross sectional view of a SiP 600 with packaged component 603 according to one embodiment. As shown in FIG. 6A, the packaged component 603 is attached to a substrate 601 using a BGA 604. The encapsulant 602, which ultimately hardens and creates the package, is shown in FIG. 6A as encasing the packaged component 603, among other devices and components on the substrate 601. As shown in FIG. 6A, the encapsulated portions in the immediate vicinity (between the attachment balls 604) of vents 611, 612 do not contain voids, while a void 608 is created in an area without the vents 611, 612. As described above, the vents 611, 612 provide new paths for any trapped gasses to escape out from under the package 603 during the encapsulation process. In the embodiment shown in FIG. 6A, the vents 611, 612 are part of the packaged component 603. For completeness, the SiP 600 is also depicted as having external attachment balls 604.

FIG. 6B depicts a cross sectional view of a SiP 650 with a packaged component 653 according to one embodiment. The packaged component 653 is attached to a substrate 651 using a BGA 654. The encapsulant 652 is shown in FIG. 6B as encasing the packaged component 653, and other devices and components on the substrate. As shown in FIG. 6B, the encapsulated portions in the immediate vicinity (between the attachment balls 654) of vents 661 and 662 do not contain voids, while a void 658 is created in an area without the vents 661, 662. In the embodiment shown in FIG. 6B, the vents 661 and 662 are part of the substrate 651. In this example, the vents are formed in the top surface of the substrate. For completeness, the SiP 650 is also depicted as having external attachment balls 657.

FIG. 6C depicts a cross sectional view of a SiP 680 with packaged component 603 during an encapsulation process according to one embodiment. As shown in FIG. 6C, the packaged component 603 is attached to the surface 610 of a SiP substrate 601 of the SiP 680 with rows of attachment balls 604 and is being encapsulated with encapsulant 602. In some embodiments, a vent 561 is part of the surface of the substrate 601 below a void 691. The vent 561 is properly placed and sized such that the void 691 does not exist by the end of the encapsulation process. The vent 561 provides a pathway for any entrapped gasses to escape during the encapsulation process. For completeness, the SiP 680 is also depicted as having external attachment balls 607.

FIG. 6D depicts a cross sectional view of a SiP 690 with a packaged component 603 during an encapsulation process according to one embodiment. As shown in FIG. 6D, the packaged component 603 is attached to the surface 610 of a SiP substrate 601 of the SiP 690 with the rows of attachment balls 604, and encapsulated by encapsulant 602. In some embodiments, additional physical obstacles 695 are implemented between the packaged component 603 and the substrate 601. The physical obstacles 695 may be on the surface of the substrate 601 below potential void locations 691. In some alternative embodiments, the physical obstacles 695 may be placed on the bottom of the packaged component 603 between the arrays of the balls 604. The obstacles 695 are configured to speed up the encapsulant 602 flow to be similar to that passing through the ball arrays and thereby avoid the u-shaped front and any potential for reverse flow void creation. Accordingly, the potential void location 691 will be filled with encapsulant without any voids by the end of the encapsulation process. For completeness, the SiP 690 is also depicted as having external attachment balls 607.

Although the examples above describe embodiments using Ball Grid Arrays, other connection means such as, but not limited to leaded and leadless packages, may be employed in alternative embodiments.

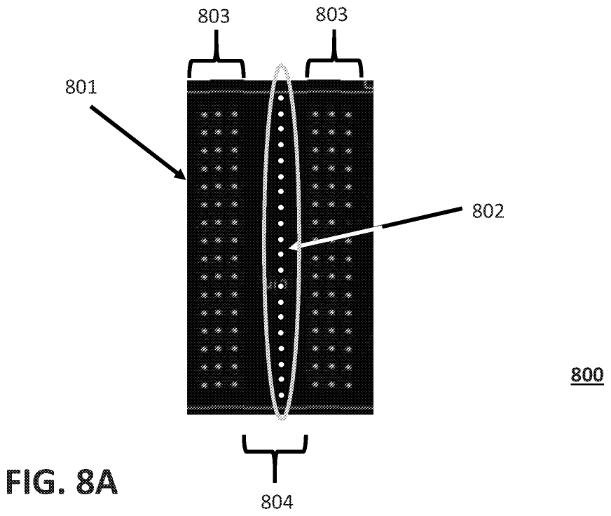

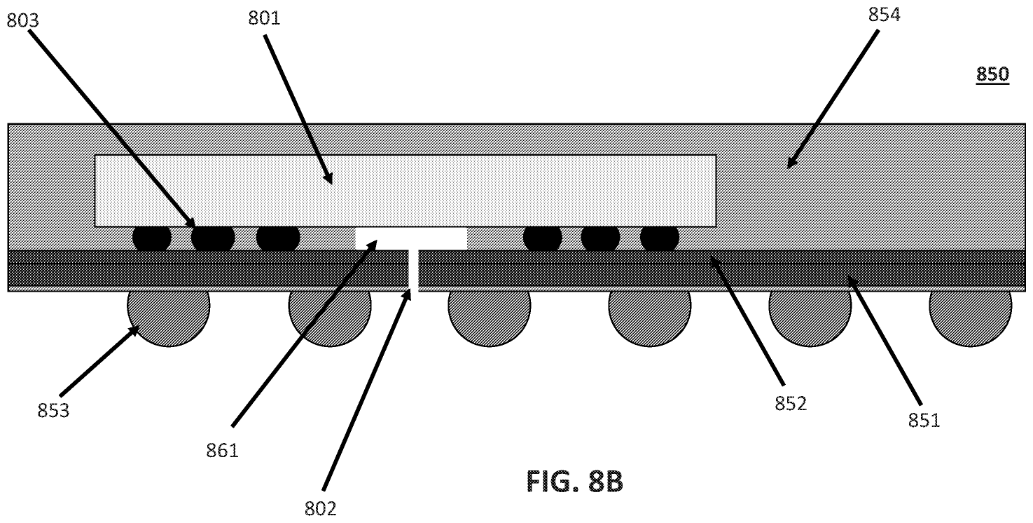

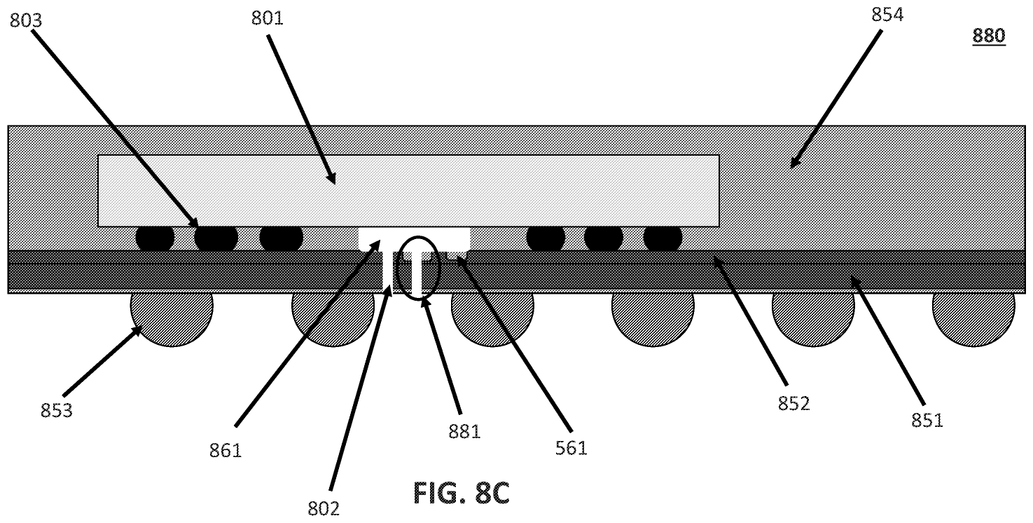

Although the embodiments of FIGS. 6A, 6B, 6C, and 6D are separately illustrated, their void elimination elements and associated descriptions may be used together. One or more of vents on a package surface, vents on a substrate surface, and physical obstacles can be used together according to embodiments. Similarly, void elimination element of the embodiments of FIGS. 6A, 6B, 6C, and 6D can be combined with one or more of the techniques described with respect to FIGS. 8A, 8B, and 8C. For example, a via in a substrate may be combined with one or more of vents on a package surface, vents on a substrate surface, and physical obstacles.

FIGS. 7A, 7B, 7C, and 7D depict methods of the present disclosure for preventing voids underneath a packaged device on a SiP substrate during packaging of the SiP. These methods may be used, for example, to manufacture a device according to one or more of FIGS. 6A, 6B, 6C, 6D, 8A, 8B, 8C, and 9A.

FIG. 7A depicts a method 700 for creating a packaged SiP system that includes packaged devices and components in a final SiP packaged device, according to embodiments. The package of a packaged device or component is modified to include one or more channels or vents on the external surface (e.g., on a bottom surface or connection side) of the package (step 701). This modified package is then “SiP ready” (e.g., like that shown in FIG. 6A) for packaging as part of a SiP. The modified package or SiP ready package is mounted on the SiP substrate as part of the assembly process, and then the packaging process for the SiP (step 702) is developed. That can included, for instance, creations of a mold based on the design of the SiP ready package. This step can include altering a molding tool as required, for instance, based on the design of the SiP ready package. Finally, the modified packaged device or component is then assembled on the SiP substrate along with the other devices and components needed for the SiP, and then the whole assembly is packaged using encapsulant materials and packaging forms to mold the package for the SiP device (step 703) around all the devices and components included on the SiP substrate.

FIG. 7B depicts a method 720 for creating a packaged SiP system, according to embodiments, that includes already packaged devices and components in a final SiP packaged device by etching vents in the SiP substrate (e.g., like that of FIG. 6B). First the SiP substrate is manufactured including the solder mask on a top surface of the SiP substrate (step 721). The solder mask on the top surface of the substrate, along with the top surface of the substrate, is etched as necessary to create vents between the landing pads and surfaces where a packaged device or component would be placed and mounted (step 722). Next, the packaged device or component is assembled on the SiP substrate in the area containing the etched positions, along with the other devices and components (step 723), and then the whole assembly is packaged using encapsulant materials and packaging forms to mold the package for the SiP device (step 724). The process can include adjusting one or more encapsulation tools.

FIG. 7C depicts an alternative method 740 of the present disclosure to create a packaged SiP system that includes previously packaged devices and components in a final SiP packaged device by putting vents in the substrate (e.g., like that of FIG. 6C). The vents are created by designing the substrate to include appropriately placed vias or holes through the substrate as vents (step 741). Next the SiP substrate is manufactured (step 742) with a step of etching the solder mask to open the holes to the top surface of the substrate (step 743). Next, the packaged device or component is then assembled on the SiP substrate in the area of the substrate containing the vias or holes, along with the other devices and components (step 744). The whole assembly is then packaged using encapsulant materials and packaging forms to mold the package for the SiP device (step 745). When the SiP is assembled and encapsulated, the SiP is completed and packaged with the voids eliminated via the air vents.

According to some embodiments, FIG. 7D depicts a method 760 for designing vents (for example, 611, 612, 661, 662, 561, 802) on the SiP substrate to eliminate voids in the encapsulant between circuits, such as a packaged device, and the substrate surface. The method uses a simulation program designed to evaluate the encapsulant flow to ensure the elimination of voids, as well as prevent any other associated issues such as, but not limited to wire sweep, etc. The first step of the process is to build a simulation model of the assembled SiP substrate (step 761). Once the model is created, it is used in a (Mold Flow) program (step 762) to simulate the flow of the encapsulant during the molding process. The results of the program are evaluated (step 763) to determine whether voids between the packaged devices and substrate are present. If voids are present (step 771), then the model is modified to include vents (step 764). Vents may be grooves, channel, or holes in the package or in the substrate, for example. For instance, one or more vents may be used as illustrated with respect to any of FIGS. 6A, 6B, 6C, 6D, 8A, 8B, 8C, and 9A. If vents are already included in the design, then the vents are appropriately modified. Once the modifications/alterations are complete, the simulation model is rerun (step 762) and re-evaluated (step 763) until voids between the packaged device and substrate are determined to be eliminated (step 772). Once the voids are determined to be eliminated in the simulation program, the design of the substrate is altered to match the simulation model (step 765). It should be noted that the simulation of the encapsulant flow direction through the SiP package form may be modified and may result in the elimination of any potential voids.

In some embodiments, a method of modeling the SiP structure may comprise manufacturing the SiP substrate and attaching its associated components and then encapsulating that physical arrangement. Such embodiments may be in addition to or used as an alternative to using the software to model the SiP structure (devices, components and packaged components correctly located on a substrate for analysis for packaging voids). Once packaged, the package can be tested to detect any voids. In some embodiments, testing may use ultrasonics, x-rays or any other method that “sees” through the package nondestructively. If voids under a packaged device are detected, their size and location are measured. Properly located vents are then designed and included in a limited number of modified, sample substrates, which are then assembled and encapsulated. The packaged SiP using the modified substrate is then tested for voids. If there are no voids, the modified substrate is used for commercially manufacturing the desired SiP product. If there are still voids, then the size and location are measured and additional modifications made to substrate design to prevent these voids. The revised design is manufactured, assembled and packaged. The package is then re-tested. Design modifications are made to the substrate design until no voids are detected, using assembled and packaged SiPs, and using the latest design of substrate. It should be noted that even for the software simulations, the modified substrate can be manufactured, assembled and packaged and then tested to confirm removal of voids, before commencing full release for commercial manufacturing of the SiP using a modified substrate.

FIG. 8A shows a semi-transparent top view 800 of a SiP configured to eliminate voids, e.g., gas bubbles, using open vias and/or holes passing through the SiP substrate according to an embodiment. FIGS. 8B and 8C show a cross sectional view of a SiP 850,880 according to embodiments.

As shown in FIG. 8A, the packaged component 801 comprises two sets of three rows of external connection balls 803a-b for connection to other components, a circuit board or a substrate (not fully shown in FIG. 8A) with a wide space 804 between the two sets 803a-b. In the middle of the two sets of arrays of connection balls 803a-b is a column of open vias or holes 802 in the substrate of a SiP. The location of the open vias or holes 802 may be changed to optimize the prevention of voids in alternative embodiments. Each of these vias or holes 802 may then be used as vents (e.g., as described above) for gasses to escape from under the packaged component 801. In some embodiments, each of these vias or holes 802 may comprise a diameter of 5 to 100 um. Although FIG. 8A shows a single column of vias 802, the may be multiple columns or any number of vias placed in a random pattern to optimize the venting in alternative embodiments.

FIG. 8B depicts a cross sectional view of the packaged component 801 attached to a SiP substrate 851 using the connection balls 803a-b of the packaged device 801. The SiP 850 is encapsulated with encapsulant 854 and connection balls 853 are attached to a surface of the SiP that is not encapsulated. FIG. 8B depicts, by way of a simplified non-limiting example, only one of the vias 802 extending through the substrate 851 and solder mask 852. However, numerous vias may be used. As the encapsulant 854 flows under the packaged device 801 any potential void 861, such as an air bubble, vents through the via 802. The size of the via 802 may be selected such that gases may vented out, but keeps the encapsulant 854 in. The size of the via 802 is also configured such that the encapsulant 854 does not fill the via 802. If any encapsulant 854 does fill a via 802, any excess encapsulant extruded through the via 802 may need to be removed from the bottom surface of the substrate 851 before the connection balls 853 of the substrate are attached.

FIG. 8C shows a cross sectional view of an embodiment comprising multiple vents 561 in combination with multiple vias 802. The vents 561 and vias 802 may be used independently of each other. The vents 561 and vias 802 may also be used in combination as shown as 881 in FIG. 8C.

According to embodiments, the void elimination techniques discussed herein can be applied, for instance, to devices and components. This may include, for example, a device having multiple components, such as a SiP device and/or a System on Chip (SoC) device, as well as individual components (e.g., capacitors, wires, etc.).

In addition to voids under components mounted on a substrate to form a SiP, a SiP may also contain an RF generating (or sensitive) component that requires shielding to avoid interfering with other components of the SiP. Accordingly the RF generating component in the SiP (or packaged integrated circuit device) may have an RF blocking enclosure around it to limit unwanted RF signals from affecting other SiP components; or an RF blocking enclosure may be placed around a component whose operation is susceptible to being adversely affected by RF to avoid such operational disruption. Such an RF generating or sensitive component may be, for instance, any of the packaged components shown with respect to FIGS. 6A, 6B, 6C, 6D, 8A, 8B, and 8C, and the associated void elimination techniques described herein.

Adding an RF blocking enclosure in the SiP protects the other SiP components (or protects an RF sensitive packaged components), but provides opportunities for voids to form in the enclosure during the process of SiP packaging encapsulation. And those voids exhibit the same problems that are inherent with voids as noted earlier herein. Thus, additional steps can be taken when packaging a SiP containing an RF generating component (or an RF sensitive component) having an RF blocking enclosure around it, while also preventing voids underneath the actual RF generating component itself, as described earlier herein.

Accordingly, some embodiments of the present disclosure relate to providing RF shielding structures for devices, such as wireless devices, that are suitable for use in encapsulated systems and products, such as in SiPs. In some embodiments, the molding compound or encapsulant material may include a resin or plastic material, thermosetting or thermoplastic resin, as well as ceramic materials. The molding compound may flow in liquid form around and through the RF shielding structures of some embodiments, enabling effective molding. In certain aspects, the RF shields may employ a metallic structure (or container) covering the RF generating component to keep any unintended RF in the structure with the RF generating component, or alternatively a metallic structure may be placed over a low noise component to shield this component from external RF radiation. In addition to metallic structures, the shield may be formed of other materials capable of blocking RF radiation. In some embodiments, the wireless components in any system may require shielding to prevent stray EMI radiation from the RF generating component from affecting nearby components or systems.

In particular, structures that enable the effective flow of a molding compound while providing sufficient EMI reduction are important as RF devices continue to increase in operational frequency. That is, at increased frequencies, even relatively “small” openings to allow the flow of molding compound can be “large” in terms of allowing RF radiation to enter or exit. By way of example, at 300 GHz, a quarter-wavelength is only 0.25 mm.

A SiP may contain an RF device within it that is prone to emit stray EMI radiations. Such radiations are undesirable as they may interfere with the function of adjacent devices of nearby systems or other components in the SiP. Further, the function of the RF device or other devices in a SIP may be compromised by RF radiation coming from outside of the RF device or the SIP. EMI emissions or radiations are strictly controlled by regulations such as those from the FCC.

FIG. 9A depicts an example of an embodiment that illustrates this arrangement of an RF generating component having an RF blocking enclosure around it in a packaged SiP, along with other components as part of the SiP. During the packaging process for the SiP, embodiments described herein may be employed to prevent voids in the RF blocking enclosure, as well as preventing voids underneath the actual RF generating component itself. This may be accomplished by providing a plurality of openings along the sides adjacent the substrate and top of the RF blocking enclosure to allow liquid encapsulant to freely flow into the enclosure to fill in above, around and under the RF generating component itself. For example, one or more vents may be used as illustrated with respect to any of FIGS. 6A, 6B, 6C, 6D, 8A, 8B, and 8C. This could include, for instance, the use of vents on a package/blocking element surface, vents on a substrate surface or vias, and physical obstacles.

In some instances, the embodiments disclosed herein may further comprise one or more embodiments of a metallic Electro-Magnetic Interference (EMI) shielding structure.

Referring to FIG. 9A, this figure depicts a side view of an RF shielding structure in a molded SiP package 900 having a substrate 906, according to some embodiments. In this example, structure 901 has a baffled structure or baffled opening 902 with a flap. In this arrangement, the RF radiation is further reduced. The opening (904) may be the opening when the shield is formed as a spiral. That is, a louvered slot EMI shielding structure 901 which comprises a separate flap 902 at the opening or slot, effectively reduces 903 EMI radiation in accordance with the teachings of the present disclosure. As shown in FIG. 9A, molding compound 905 fills the gap under shielding structure 901 and under the RF generating or sensitive component 910.

In certain aspects, a shield for an EMI or RF generating component is mounted on a substrate for an integrated circuit device, where said device is to be encapsulated as part of its packaging, that includes a metallic container mounted over said EMI or RF generating component and having openings on the top and at least one side to allow liquid encapsulant to flow into said container and fully encapsulate said EMI or RF generating component when said device is being encapsulated, wherein said openings allow encapsulant to enter and fill up said container while substantially reducing electro-magnetic radiation from said EMI or RF generating component from leaving said container.

According to some embodiments, the openings or apertures in the walls adjacent the substrate are provided as baffle features in the side walls or top, respectively, which comprise an opening and a flap sized to allow molding compound or encapsulant to enter the RF shielding structure during encapsulation, while minimizing the RF radiation passing through the opening. In some aspects, the baffled opening may allow the mold compound to enter and fill the RF shielding structure without forming any voids or air gaps. Accordingly, the RF shielding structure can enable effective molding while reducing the chances of significant radiation escaping (or entering) through the baffled opening, thus, preventing potential interference with other devices. In an embodiment, the baffle features may be positioned on the structure such that they are approximately ninety degrees to the incident radiation for maximum effectiveness in blocking and/or absorption.

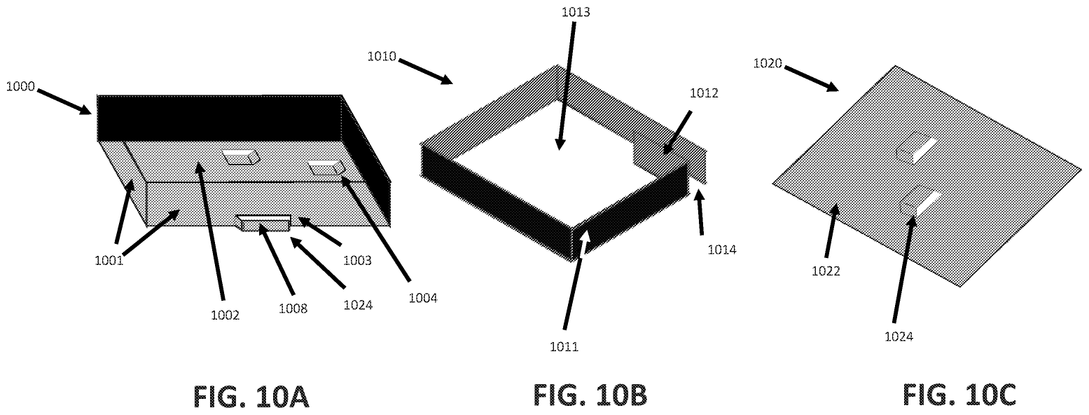

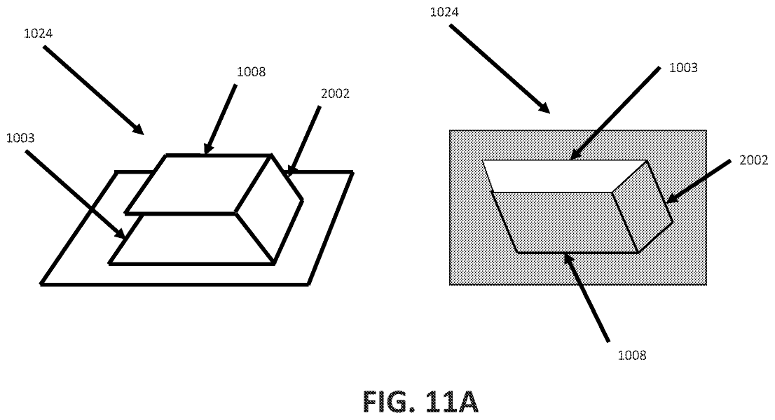

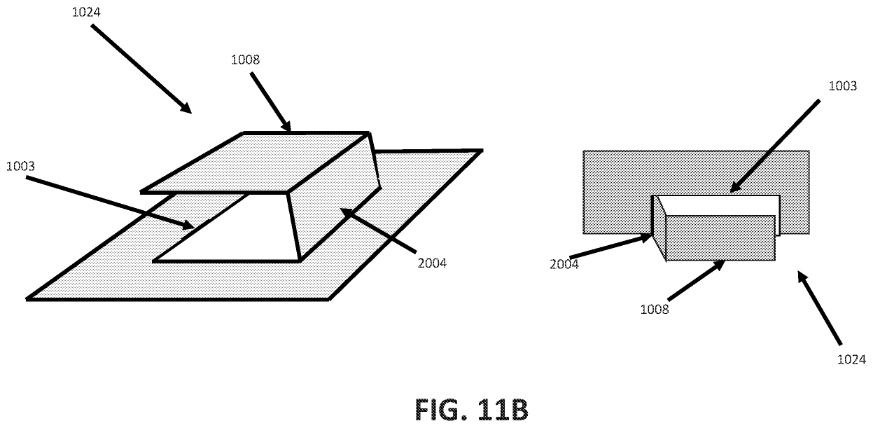

FIG. 9B depicts a process 940 for manufacturing a molded integrated circuit. This may be, for instance, a SIP device. In step 941, an RF shield, such as a shield depicted with respect to FIGS. 10A-10C, 11A, and 11B, is placed over an RF component of an integrated circuit. In step 942, a molding operation is performed on the integrated circuit such that molding compound flows into the RF shield. According to embodiments, steps 941 and 942 are performed in accordance with one or more of the methods described with respect to FIGS. 7A, 7B, 7C, and 7D.

FIGS. 10A-10C depict RF or EMI shielding structures according to some embodiments of the present disclosure. For instance, FIG. 10A depicts an RF shielding structure 1000 with side walls 1001 and top wall 1002. The RF shielding structure 1000 can be used to shield other devices from RF radiation, as well as to protect a device from RF radiation due to other devices or external sources. In an embodiment, the RF structure 1000 is in the shape of a rectangular can and sized to fit over and around an RF generating chip or component, for instance, an RF device contained within an SIP. While the structure is depicted in a rectangular configuration, it may also, for example, but not limited to, be round, contain rounded walls, and include more or less than four walls, according to some embodiments. Additionally, for certain applications, the top 1002 may be excluded. In the example of FIG. 10A, the RF shielding structure 1000 is provided with apertures (e.g., holes or slots) to allow molding compound to enter and air to be vented out of the RF shielding structure 1000.

According to some embodiments, the apertures are provided as baffle features 1024 or 1004 in the side walls 1001 or top 1002, respectively, which comprise an opening 1003 and a flap 1008 made to allow molding compound or encapsulant to enter the RF shielding structure 1000 during encapsulation, while minimizing the RF radiation passing through the opening. In some aspects, the baffled opening 1003 can allow the mold compound to enter and fill the RF shielding structure 1000 without forming any voids or air gaps. Accordingly, the RF shielding structure 1000 can enable effective molding while reducing the chances of significant radiation escaping (or entering) through the baffled opening 1003, thus, preventing potential interference with other devices. In an embodiment, the baffle features 1024 may be positioned on the structure such that they are approximately 90 degrees to the incident radiation for maximum effectiveness in blocking and/or absorption.

In some embodiments, the encapsulating material (molding compound) is a thermosetting plastic material with fillers, such as silica, in it. In this example, when the molding compound or encapsulant is heated to a certain temperature it melts, attains a very low viscosity for a short period of time, and then it gels and hardens. While it is in liquid form it completely fills the package mold cavity. In the case of a SiP, the mold compound or encapsulant should not only fill the mold cavity but also fill around and below the components that have been previously mounted on a SIP substrate. In some embodiments, all the components may be mounted on a SiP substrate such that each of these components have sufficient clearance above the SIP substrate for encapsulant to flow between the bottom of the component and the substrate. This allows the encapsulant to flow underneath the component and all around it to form a void free SiP package. In certain aspects, the shielding structures depicted in FIGS. 10A-10C do not interfere with this process.

As illustrated in FIG. 10A, baffle features 1004 with flaps are included on the top 1002 of structure 1000 to allow the mold compound or encapsulant to flow through it also. The features 1004 can minimize, or even eliminate, voids in the mold compound within the RF shielding structure 1000. In certain aspects, the RF shielding structure's material is specifically chosen to minimize the amount of RF radiation that is emitted either by absorbing the energy or by containing it, such as a metal. Such RF-blocking materials can include, for example, not only metals, but other electrically conductive materials.

FIG. 10B depicts a structure 1010 used for shielding EMI radiations from a RF device according to some embodiments. RF shielding structure 1010 may be made, for instance, of metal. In this embodiment, it comprises a spiral-shaped sheet of metal 1011 that is formed around the RF device in a way that totally encompasses the perimeter of the RF device and has an over lapping section 1012. That is, a first portion of a wall overlaps a second portion of the wall. The resulting shape forms an RF shielding structure 1010 with an overlap, which comprises an opening 1014 for encapsulant to fill in the space 1013 between the RF device and the structure 1010.

In some embodiments, the spiral-shaped wall 1011 of FIG. 10B may also be covered with a flat piece of material 1020, such as metal, as shown in FIG. 10C. In this example, top 1020 may include baffle features 1024 in the layer 1022 to allow trapped air to escape and encapsulant to enter and fill up the space as it displaces the air. The spiral shape allows encapsulant to enter but blocks EMI radiation from exiting (or entering) the structure. In some instances, the flat piece 1020, which is used as a lid as shown in FIG. 10C, may not be necessary if only the other circuits or components on the SIP substrate are to be protected from RF signals. If the flat piece 1020 is eliminated, it could allow for even better flow of the mold compound to eliminate encapsulant voids in it, but could still, protect other circuits from RF generated by an RF device. For instance, by blocking radiation in a laterally outward direction from the device.

According to some embodiments, the baffle feature 1024, with opening 1003 and flap 1008, may be formed in different configurations, for instance, as illustrated in FIGS. 11A and 11B. For example, FIG. 11A illustrates baffle feature 1024 with the flap 1008 connected to the opening 1003 via a connecting part 2002 configured at an angle smaller than a right angle. In another example, FIG. 11B illustrates feature 1024 with the flap 1008 connected to the opening 1003 via a connecting part 2004 configured at a right angle. In an embodiment, the baffle features 1024 may be formed on either surface of the flat piece of metal 1022. Additionally, as shown in these figures, the flap portion may extend into, or outward from, the RF shielding structure.

In certain aspects, a shield for an EMI or RF generating component is mounted on a substrate for an integrated circuit device, where said device is to be encapsulated as part of its packaging, that includes a metallic container mounted over said EMI or RF generating component (or EMI or RF sensitive component) and having openings on the top and at least one side to allow liquid encapsulant to flow into said container and fully encapsulate said EMI or RF generating component when said device is being encapsulated, wherein said openings allow encapsulant to enter and fill up said container while substantially reducing electro-magnetic radiation from said EMI or RF generating component from leaving said container.

While various embodiments of the present disclosure are described herein, it should be understood that they have been presented by way of example only, and not limitation. Thus, the breadth and scope of the present disclosure should not be limited by any of the above-described exemplary embodiments. Moreover, any combination of the above-described elements in all possible variations thereof is encompassed by the disclosure unless otherwise indicated herein or otherwise clearly contradicted by context.

Additionally, while the processes described above and illustrated in the drawings are shown as a sequence of steps, this was done solely for the sake of illustration. Accordingly, it is contemplated that some steps may be added, some steps may be omitted, the order of the steps may be re-arranged, and some steps may be performed in parallel.

1. A packaged device, comprising:
(a) a packaged integrated circuit device, comprising:
a substrate; and
a packaged component attached to said substrate, wherein said packaged component comprises at least one vent on a bottom surface of said packaged component, or
(b) a packaged SiP device, comprising:
a substrate, wherein said substrate comprises a vent in a top surface of said substrate at a first location; and
a packaged component, wherein said packaged component is attached to said substrate at said first location; or
(c) said packaged device comprising a packaged SiP device, comprising:
a substrate comprising an opening in said substrate that extends entirely through said substrate; and
a packaged component attached to said substrate and located over said opening.

2. The packaged integrated circuit device of claim 1, further comprising:
an electromagnetic radiation blocking element mounted over a radiation generating or sensitive component mounted on said substrate,
wherein said radiation blocking element comprises at least one opening in a side adjacent said substrate.

3. The packaged integrated circuit device of claim 1, wherein encapsulant between said packaged component and said substrate contains no voids in a region adjacent said vent on said bottom surface of said packaged component.

4. The packaged integrated circuit device of claim 2, wherein said radiation blocking element further comprises an opening on the top of said element.

5. The packaged integrated circuit device of claim 2, wherein said radiation generating or sensitive component mounted on said substrate comprises vents on its bottom surface.

6. The packaged integrated circuit device of claim 1, further comprising:
a plurality of other devices and components operatively mounted on said substrate.

7. The packaged integrated circuit device of claim 6, wherein said device is a packaged SiP device.

8-9. (canceled)

10. The packaged SiP device of claim 1, wherein encapsulant located between said substrate and said packaged component is free of voids.

11. (canceled)

12. A method comprising:
a) a method for packaging an integrated circuit device, comprising:
providing a substrate;
attaching a packaged component to said substrate, wherein the packaged component comprises a vent on a bottom surface of said packaged component, wherein the bottom surface of the packaged component faces a top surface of the substrate;
placing said substrate and the attached packaged component in a packaging mold; and
injecting an encapsulant into the packaging mold to create a package enclosing the substrate and the packaged component,
wherein the encapsulant flows between the substrate and the packaged component,
wherein any void formation while enclosing the substrate and the packaged component with the encapsulant is prevented by said vent, and
wherein said vent is configured to allow gases trapped in the encapsulant to escape; or
b) said method comprising a method for creating a substrate for a SiP device containing at least one packaged component using a scale model of the SiP device containing at least one packaged component and said substrate, wherein said at least one packaged component is attached to a surface of the substrate, comprising:
simulating the flow of liquid encapsulant through said scale model of the SiP device;
analyzing the simulation for any voids in the encapsulant between any one of the at least one packaged component and the substrate;
modifying said SiP model to mitigate any voids, wherein modifying the design includes modifying said substrate which comprises any one of: modifying the substrate to include one or more vents or holes on a surface, and modifying any existing vents or holes on the substrate to mitigate any voids and modifying at least one of the at least one packaged components to include vents on its bottom mounting surface, modifying existing vents in said bottom mounting surface to mitigate any voids;
simulating the flow of encapsulant for packaging the scale model of the SiP device using the modified design of the substrate;
analyzing the simulation for any voids between the packaged component and the modified design of the substrate;
repeating simulations with incremental substrate modifications until there are no voids between the packaged component and the modified design of the substrate; and
creating the substrate with the modified design of the substrate that result in no voids; or
c) said method comprising a method for designing a substrate for a SiP device containing at least one packaged component, comprising:
creating a substrate design for said SiP device, wherein the substrate design comprises at least one vent over which each packaged component is to be mounted;
manufacturing the substrate for the SiP device, wherein the substrate comprises the at least one vent for each packaged component:
assembling SiP components and at least one packaged component on said substrate; and
encapsulating the components into a SiP package; or
d) said method comprising a method for creating a void free SiP device using a substrate containing at least one packaged device, comprising:
assembling the SiP device, wherein assembling the SiP device comprises assembling SiP components on said substrate including said at least one packaged device; encapsulating said SiP to package said SiP;
testing said packaged SiP device for voids;
detecting the presence of voids in said packaged SiP;
modifying the design of said substrate or components to include vents, or modify any existing vents to determine if further testing determines that existing or modified vents mitigate any voids;
modifying the design of said SiP to properly space any included packaged devices or other devices or components to determine if testing determines that spacing mitigates any voids;
encapsulating said SiP using said modified design of said substrate, components and SiP;
analyzing said packaged SiP employing said modified design of said substrate and SiP simulation for any voids in said package;
continuing the foregoing steps with additional incremental substrate, component, and SiP design modifications until there are no voids; and
assembling said SiP using said modified substrate and SiP design.

13. The method of claim 12, further comprising:
configuring said substrate to contain vents or openings and operatively mounting a plurality of other devices and components on said substrate over said vents or openings.

14. The method of claim 13, wherein said device is a SiP device.

15. The method of claim 14, further comprising:
operatively mounting a plurality of other devices and components on said substrate before injecting the encapsulant into the packaging mold.

16-17. (canceled)

18. The method of claim 12, wherein manufacturing the substrate comprises etching a solder mask on the substrate to create an opening for the at least one vent.

19. The method of claim 12, further comprising:
mounting an RF generating or sensitive packaged component mounted on said substrate, and assembling a radiation blocking element having at least one opening in at least one side adjacent said substrate over said RF generating or sensitive packaged component.

20. The method of claim 19, wherein said radiation blocking element further comprises an opening on the top of said element.

21. The method of claim 12, wherein a thickness of said SiP package is minimized and adjusted to cover each of said packaged device and maintain SiP package structural integrity.

22. The method of claim 12, wherein said one or more vents comprise additional structures, channels, grooves and holes.

23. (canceled)

24. The method of claim 12, further comprising:
assembling the SiP device, wherein assembling the SiP device comprises assembling SiP components on said substrate including said at least one packaged device and a radiation generating or sensitive component and associated electromagnetic radiation blocking element having at least one opening in at least one side adjacent said substrate serving as a vent.

25. The method of claim 12, wherein said vents comprise channels, grooves, and holes.
